(19) United States
(12) Patent Application Publication
(10) Pub. No.: US 2024/0355709 A1
(43) Pub. Date: Oct. 24, 2024

(54) SEMICONDUCTOR PACKAGE

(71) Applicant: SAMSUNG ELECTRONICS CO., LTD., Suwon-si (KR)

(72) Inventors: Kitae Park, Suwon-si (KR); Seonkyu Kim, Suwon-si (KR); Seungmin Baek, Suwon-si (KR); Joonseok Oh, Suwon-si (KR); Joohyung Lee, Suwon-si (KR); Junghyun Cho, Suwon-si (KR)

(21) Appl. No.: 18/637,022

(22) Filed: Apr. 16, 2024

(30) Foreign Application Priority Data
Apr. 18, 2023 (KR) 10-2023-0050915

(51) Int. Cl. H01L 23/48; H01L 23/00; H01L 23/31; H01L 23/544; H01L 25/065

(52) U.S. Cl. CPC H01L 23/481; H01L 23/3128; H01L 23/544; H01L 24/16; H01L 25/0657; H01L 2223/54426; H01L 2224/16145; H01L 2225/06513; H01L 2225/06541; H01L 2924/1815

(57) ABSTRACT

A semiconductor package includes a base chip, a first semiconductor chip on the base chip, and a first fillet layer between the base chip and the first semiconductor chip. The base chip includes a base substrate, a plurality of through-electrodes penetrating through the base substrate, a protective layer surrounding the plurality of through-electrodes and covering an upper surface of the base substrate, and a plurality of trenches vertically penetrating the protective layer. The plurality of through-electrodes form a transistor area on the base substrate, and the plurality of trenches include first trenches disposed between adjacent through-vias in the transistor area and second trenches disposed in an outer side portion of the transistor area.

### CROSS-REFERENCE TO RELATED APPLICATION(S)

This application claims the benefit under 35 USC 119(a) of Korean Patent Application No. 10-2023-0050915 filed on Apr. 18, 2023, in the Korean Intellectual Property Office, the entire disclosure of which is incorporated herein by reference for all purposes.

### BACKGROUND

To implement high performance and high reliability in miniaturized and lightweight semiconductor packages, research into and development of semiconductor chips includes forming trenches without a separate patterning process.

### SUMMARY

Implementations of this disclosure relate to semiconductor packages that can be miniaturized and have improved reliability.

According to some implementations, a semiconductor package includes a base chip, a first semiconductor chip on the base chip, and a first fillet layer between the base chip and the first semiconductor chip. The base chip includes a base substrate, a plurality of through-electrodes penetrating through the base substrate, a protective layer surrounding the plurality of through-electrodes and covering an upper surface of the base substrate, and a plurality of trenches vertically penetrating the protective layer. The plurality of through-electrodes form a transistor area on the base substrate, and the plurality of trenches include first trenches disposed between adjacent through-vias in the transistor area and second trenches disposed in an outer side portion of the transistor area.

According to some implementations, a semiconductor package includes a base chip, a first semiconductor chip on the base chip, and a first fillet layer between the base chip and the first semiconductor chip. The base chip includes a base substrate, a plurality of through-electrodes penetrating through the base substrate, a protective layer surrounding the plurality of through-electrodes and covering an upper surface of the base substrate, and a plurality of trenches vertically penetrating the protective layer. The plurality of through-electrodes form a transistor area on the base substrate, and the plurality of trenches includes an alignment trench horizontally spaced apart from the transistor area by a predetermined distance, first trenches disposed between adjacent through-electrodes in the transistor area, and second trenches disposed to surround the transistor area. Lower levels of the alignment trench, the first trenches, and the second trenches are substantially the same as each other, and the first semiconductor chip is vertically stacked on the base chip, and includes a first semiconductor substrate, a plurality of through-vias penetrating the first semiconductor substrate and forming a transistor area on the first semiconductor substrate, and first trenches disposed between adjacent through-vias in the transistor area.

According to some implementations, a semiconductor package includes a base chip, a first semiconductor chip on the base chip, a first fillet layer between the base chip and the first semiconductor chip, and a molding member disposed on the base chip and surrounding a side surface of the first fillet layer and a side surface of the first semiconductor chip. The base chip includes a base substrate, a plurality of through-vias penetrating the base substrate and providing a transistor area on the base substrate, a protective layer surrounding the plurality of through-vias and covering an upper surface of the base substrate, an alignment trench spaced apart from the transistor area in a horizontal direction and disposed near a vertex of an upper surface of the base chip, first trenches disposed between adjacent through-vias in the transistor area and filled with the first fillet layer, and second trenches disposed in an outer side portion of the transistor area and filled with the first fillet layer and the molding member. Lower levels of the alignment trench, the first trenches, and the second trenches are on substantially the same level as each other, and are at a level lower than a lower level of the protective layer. The first fillet layer filled in the first trenches contacts the base substrate and forms a first heterogeneous interface, and the first fillet layer and the molding member filled in the second trenches contact the base substrate and form a second heterogeneous interface.

### BRIEF DESCRIPTION OF THE DRAWINGS

The above and other aspects, features, and advantages of the present disclosure will be more clearly understood from the following detailed description, taken in conjunction with the accompanying drawings, in which:

FIG. 1 is a cross-sectional view illustrating a semiconductor package according to some implementations;

FIG. 2 is a cross-sectional view illustrating a cut along line I-I′ of FIG. 1;

FIG. 3 is a cross-sectional view illustrating a cut along line II-II′ of FIG. 2;

FIGS. 4A and 4B are partially enlarged views illustrating a region ‘A’ in FIG. 1;

FIG. 5 is a cross-sectional view illustrating a semiconductor package according to some implementations;

FIG. 6 is a partially enlarged view illustrating a region ‘B’ of FIG. 5;

FIG. 7 is a cross-sectional view illustrating a semiconductor package according to some implementations;

FIG. 8 is a partially enlarged view illustrating a region ‘C’ of FIG. 7;

FIG. 9 is a cross-sectional view illustrating a semiconductor package according to some implementations.

FIG. 10 is a partially enlarged view illustrating a region ‘D’ of FIG. 7.

FIG. 11 is a cross-sectional view illustrating a semiconductor package according to some implementations;

FIGS. 12A to 12J are cross-sectional views schematically illustrating a process of manufacturing a semiconductor package according to some implementations; and

FIGS. 13A to 13C are cross-sectional views taken along line III-III′ of FIG. 12E.

### DETAILED DESCRIPTION

Hereinafter, with reference to the accompanying drawings, the subject matter of the present disclosure will be described in more detail. Unless otherwise specified, in this specification, terms such as “upper”, “upper surface”, “lower”, “lower surface”, “side” and the like are based on the drawings, and in detail, can be changed depending on the direction in which components are disposed.

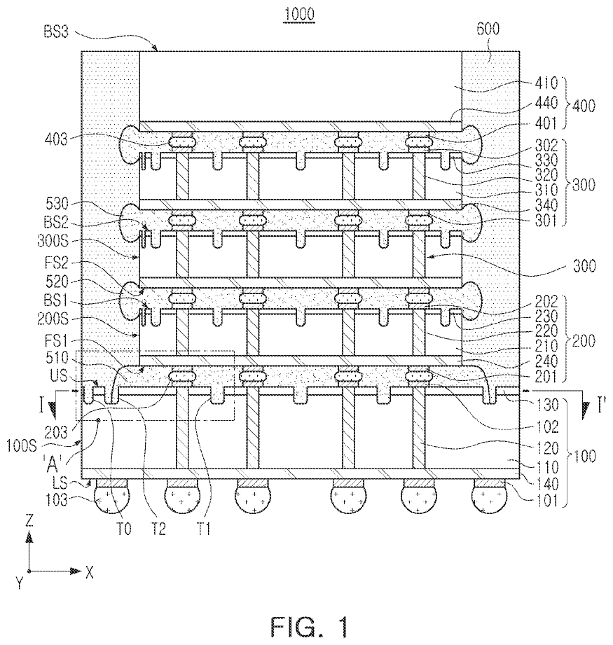

FIG. 1 is a cross-sectional view illustrating a semiconductor package 1000 according to some implementations.

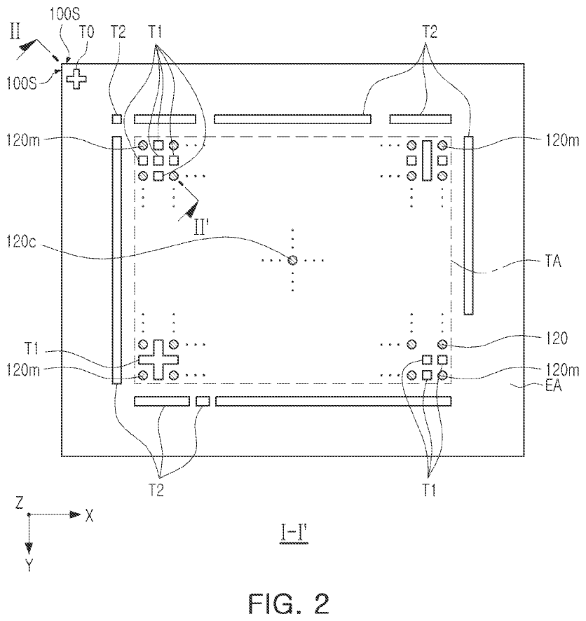

FIG. 2 is a cross-sectional view taken along line I-I′ of FIG. 1.

Referring to FIGS. 1 and 2, in an example implementation, a semiconductor package 1000 includes a plurality of semiconductor chips 200, 300 and 400 on a base chip 100, bump structures 203, 303 and 403, and at least one fillet layer (510, 520, 530) and a molding member 600. The fillet layers 510, 520, and 530 can be formed by thermal compression bonding for stacking and fixing the plurality of semiconductor chips 200, 300, and 400 on the base chip 100. The fillet layers 510, 520, and 530 can form protrusions that protrude further than side surfaces of the plurality of semiconductor chips 200, 300, and 400. The protrusions can form a heterogeneous interface on the upper surfaces of the molding member 600 and the base chip 100. The molding member 600 is formed to surround the side surfaces of the fillet layers 510, 520, and 530 and the side surfaces of the plurality of semiconductor chips 200, 300, and 400. In relation to the heterogeneous interface, a crack due to a fatigue crack can occur on the upper surface of the base chip 100. In addition, when exposed to humidity during the semiconductor package manufacturing process or the manufactured semiconductor package storage, moisture is absorbed into the semiconductor package, causing delamination of the heterogeneous interface, which can cause a decrease in reliability. According to some implementations, as the first trenches T1 and the second trenches T2 are formed to have predetermined widths and depths within the transistor area TA formed by the plurality of through-electrodes 120 and within the edge area EA surrounding the transistor area, respectively, adhesion can be improved by increasing the surface area in contact between the protrusions of the fillet layers and the molding member 600, and reliability can be secured by preventing cracks and delamination.

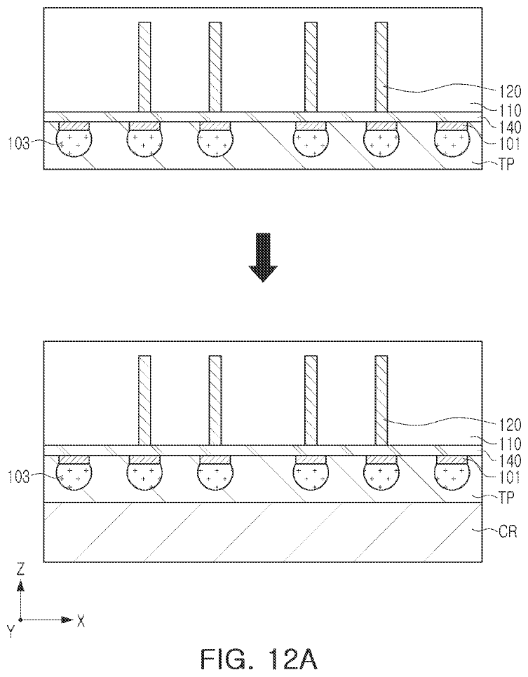

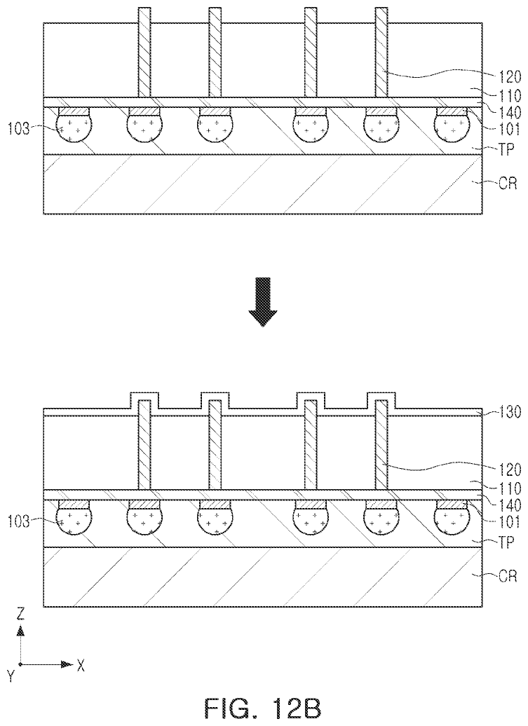

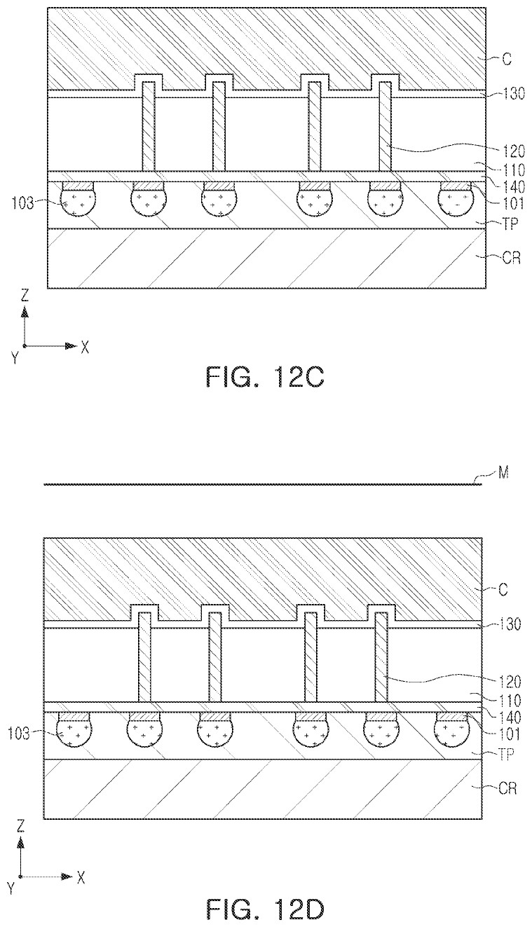

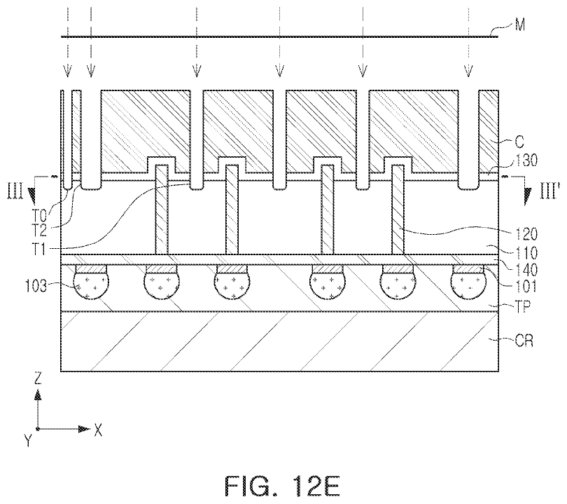

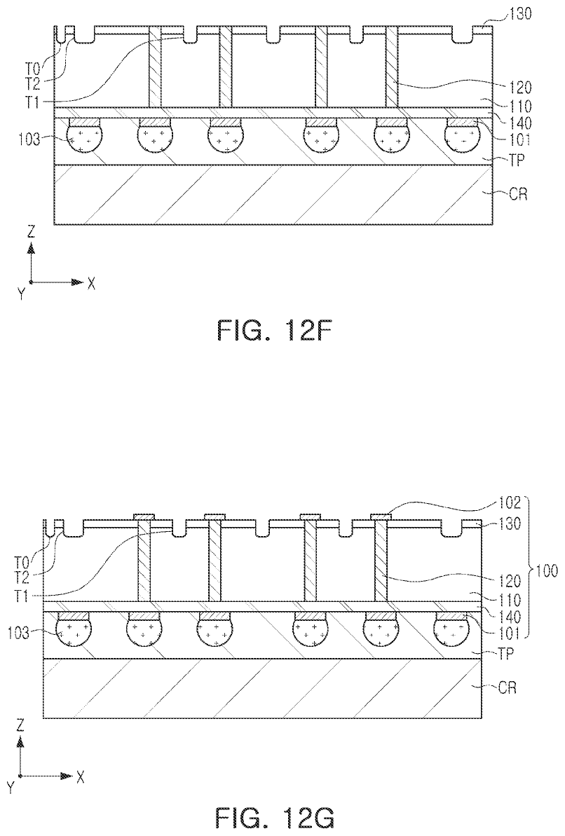

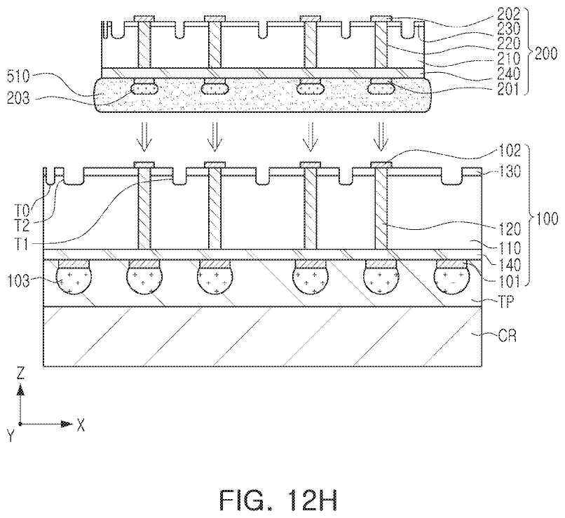

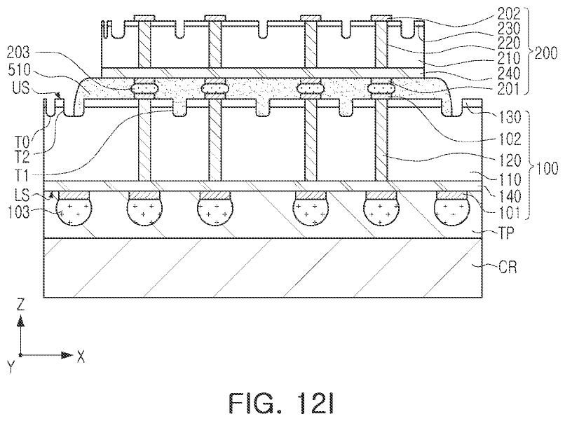

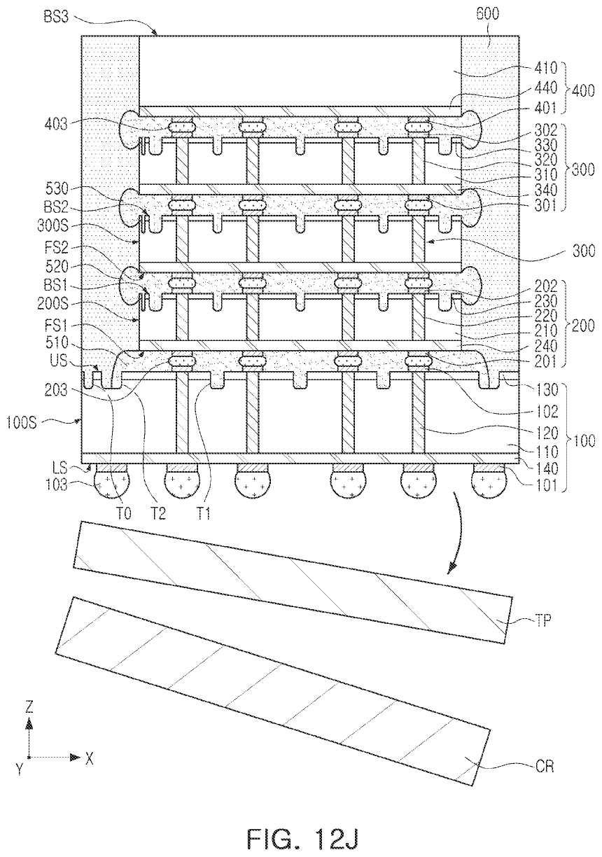

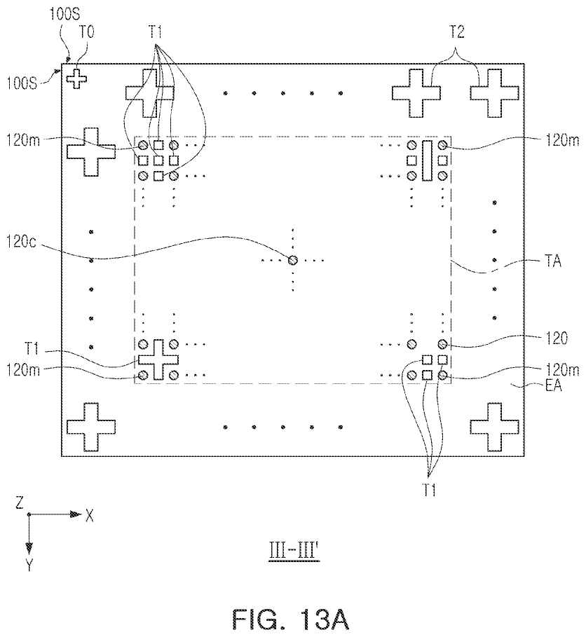

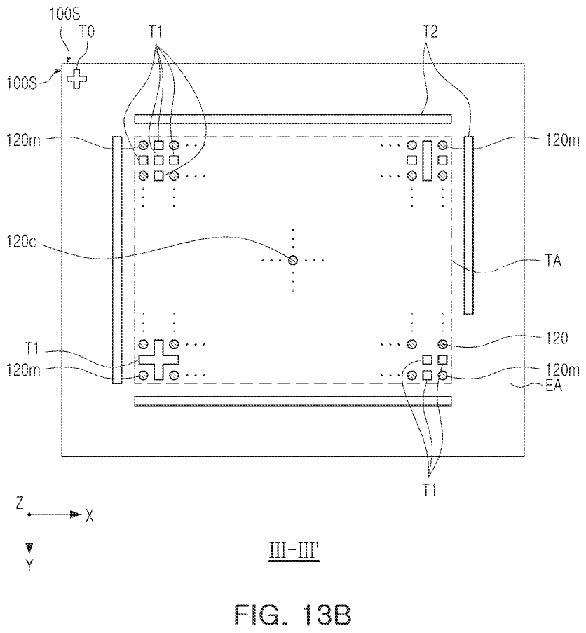

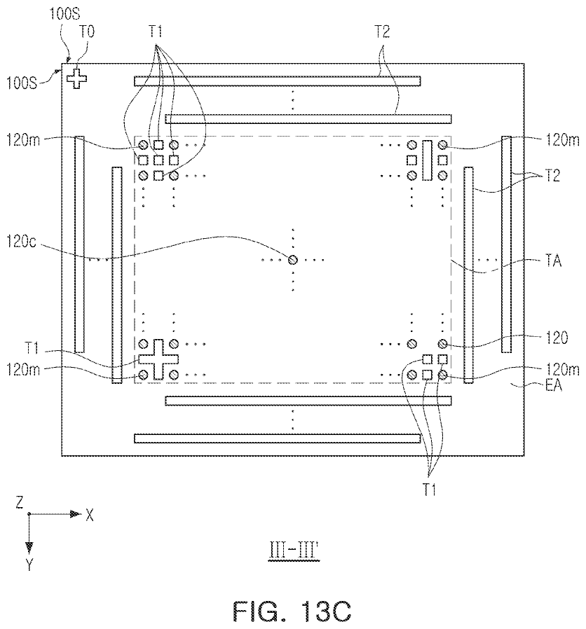

In some implementations, the first trenches T1 and the second trenches T2 are formed together with the alignment trench T0 in the process of forming an alignment key without a separate patterning process (see FIGS. 12E and 13), which can be obtained by changing the design of a photoresist patterning mask (PRP Mask). As a result, unlike the related art, a plurality of trenches can be formed without a separate patterning process. And by forming heterogeneous materials having a wider contact area inside the plurality of trenches, the semiconductor package 1000 having improved process efficiency and reliability can be implemented.

The plurality of semiconductor chips 200, 300, and 400 can be composed of memory chips or memory elements that store or output data based on address commands and control commands transmitted from the base chip 100. For example, the plurality of semiconductor chips 200, 300, and 400 can include volatile memory devices such as dynamic random-access memory (DRAM) and static random-access memory (SRAM), and non-volatile memory devices such as phase-change random-access memory (PRAM), magnetoresistive random-access memory (MRAM), Ferroelectric random-access memory (FeRAM) or resistive random-access memory (RRAM). Among the plurality of semiconductor chips 200, 300, and 400, the uppermost semiconductor chip 400 (hereinafter referred to as “third semiconductor chip”) does not include a through-via, and the back surface thereof BS3 can be exposed from the encapsulant 420, but the subject matter of the present disclosure is not limited thereto.

The first semiconductor chip 200, at least one second semiconductor chip 300, and a third semiconductor chip 400 are sequentially stacked on the base chip 100. In some implementations, the base chip 100 includes a base substrate 110, an upper protective layer 130, upper pads 102 and lower pads 101, a device layer 140, and a through-electrode 120. The base chip 100 can be, for example, a buffer chip including a plurality of logic devices and/or memory devices in the device layer 140. Accordingly, the base chip 100 can transmit signals from the plurality of semiconductor chips 200, 300, and 400 stacked in an upper portion to the outside, and in addition, can transmit external signals and power to the plurality of semiconductor chips 200, 300, and 400. The base chip 100 can perform both a logic function and a memory function through logic elements and memory elements. In contrast, in some implementations, the base chip 100 includes only logic elements and performs only logic functions.

The base substrate 110 can include, for example, a semiconductor element such as silicon (Si) or germanium (Ge), or cancan include a compound semiconductor such as silicon carbide (SiC), gallium arsenide (GaAs), indium arsenide (InAs), or indium phosphide (InP). The base substrate 110 cancan have a silicon on insulator (SOI) structure. The base substrate 110 cancan include a conductive region, for example, a well doped with impurities or a structure doped with impurities. The base substrate 110 can include various device isolation structures such as a shallow trench isolation (STI) structure.

The upper protective layer 130 can be formed on the upper surface of the base substrate 110 and can protect the base substrate 110. The upper protective layer 130 can be formed of an insulating layer such as a silicon oxide film, a silicon nitride film, or a silicon oxynitride film. The material of the upper protective layer 130 is not limited to the above materials. For example, the upper protective layer 130 can be formed of an insulating material such as a Photo-Imageable Dielectric (PID) material, and can be formed of a polymer such as polyimide (PI) or photosensitive polyimide (PSPI). The upper protective layer 130 can be formed as a single layer on the upper surface of the base substrate 110, but the subject matter of the present disclosure is not limited thereto. For example, the upper protective layer 130 can be formed of a plurality of layers in which a first protective layer 130a, a second protective layer 130b, and a third protective layer 130c are sequentially stacked on the upper surface of the base substrate 110. For example, the plurality of layers can be formed of a layer in which a silicon oxide layer, a silicon nitride layer, and a silicon oxide layer are sequentially stacked. In this case, the material of each of the plurality of layers is not limited to the above materials. Although not illustrated in the drawing, a protective layer (“lower protective layer”) can be further formed on the lower surface of the device layer 140.

The upper pad 102 can be disposed on the upper surface US of the base chip 100 (or on the upper protective layer 130). The upper pad 102 can include, for example, at least one of aluminum (Al), copper (Cu), nickel (Ni), tungsten (W), platinum (Pt), and gold (Au). The lower pad 101 can be disposed on the lower surface LS of the base chip 100 (or the lower portion of the device layer 410), and can include a material similar to a material of the upper pad 102. However, the materials of the upper pad 102 and lower pad 101 are not limited to the above materials.

The device layer 140 can be disposed on the lower surface of the base substrate 110 and can include various types of devices. For example, the device layer 140 can include a field effect transistor (FET) such as a planar FET or a FinFET, a memory element such as a flash memory, a DRAM, a SRAM, an Electrically Erasable Programmable Read-Only Memory (EEPROM), a PRAM, a MRAM, a FeRAM, a RRAM, a high bandwidth memory (HBM), and the like, a logic element such as AND, OR, and NOT, and various active and/or passive components such as system Large Scale Integration (LSI), a CMOS Imaging Sensor (CIS), and a Micro-Electro-Mechanical System (MEMS).

The device layer 140 can include an interlayer insulating layer (not illustrated) and a multilayer wiring layer (not illustrated) on the above-described devices. The interlayer insulating layer (not illustrated) can include silicon oxide or silicon nitride. The multilayer interconnection layer (not illustrated) can include multilayer interconnections and/or vertical contacts. The multi-layer wiring layer (not illustrated) can connect elements of the device layer 140 to each other, connect elements to a conductive region of the base substrate 110, or connect elements to the lower pad 101.

The through-electrodes 120 can penetrate the base substrate 110 in a vertical direction (Z direction) and provide an electrical path connecting the upper pads 102 and the lower pads 101. The through-electrodes 120 can be electrically connected to the plurality of semiconductor chips 200, 300, and 400. The through-electrodes 120 can include a conductive plug and a barrier film surrounding the conductive plug. The conductive plug can include a metal material such as tungsten (W), titanium (Ti), aluminum (Al), or copper (Cu). The conductive plug can be formed through a plating process, a PVD process, or a CVD process. The barrier layer includes titanium (Ti), titanium nitride (TiN), tantalum (Ta), or tantalum nitride (TaN), and can be formed through a plating process, a PVD process, or a CVD process. Between the side surfaces of the through-electrodes 120 and the base substrate 110, a side insulating layer (e.g., a high aspect ratio process (HARP) oxide) including an insulating material such as silicon oxide, silicon nitride, or silicon oxynitride (e.g., high aspect ratio process (HARP) oxide) not illustrated) can be formed.

The through-electrodes 120 can form a transistor area (TA) on the base substrate 110 (or upper protective layer 130) by vertically penetrating the base substrate 110. In detail, the transistor area TA is defined as an area surrounding from the through-electrodes 120c formed in the center to the through-electrodes 120m disposed at the outermost part.

The through-electrodes 120 can form an edge area EA surrounding the transistor area TA on the base substrate 110 (or the upper protective layer 130). In detail, the edge area EA is defined as an area other than the transistor area TA defined on the base substrate 110.

A plurality of trenches T0 and T1 can be formed in the transistor area TA and the edge area EA formed on the base substrate 110 (or the upper protective layer 130). The plurality of trenches T0, T1, and T2 can include an alignment trench T0, a first trench T1, and a second trench T2.

Among the plurality of trenches T0, T1, and T2, the first trench T1 can be formed between adjacent through-electrodes 120 in the transistor area TA. For example, the first trench T1 can be formed between adjacent through-electrodes 120 in the transistor area TA so as not to overlap the through-electrodes 120, and can be formed by etching the upper protective layer 130 formed on the upper surface of the base chip 110 to a predetermined depth. The first trench T1 can be formed to have the same horizontal and vertical width, but other widths are also possible.

Among the plurality of trenches T0, T1, and T2, the second trench T2 can be formed in an area surrounding the transistor area TA, for example, in the edge area EA. The second trench T2 can be formed in the edge area EA, while can be formed along a corner of the transistor area TA. The second trench T2 can be formed by etching the upper protective layer 130 formed on the upper surface of the base chip 110 to a predetermined depth in the edge area TA. The second trench T2 can be formed to extend in the X or Y longitudinal direction, but is not limited thereto. The lower level of the second trench T2 can be positioned on substantially the same level as the lower level of the first trench T1.

Among the plurality of trenches T0, T1, and T2, the alignment trench T0 can be formed at a portion spaced apart from the transistor area TA toward the corner of the base substrate 110 by a predetermined distance. The alignment trench T0 can be formed in the edge area EA and can be formed adjacent to the side surface 100S of the base substrate 110. The alignment trench T0 can be formed in the edge area EA and can be formed at a vertex portion where the side surfaces 100S of the base substrate 110 (or the side surfaces of the upper protective layer 130) meet. The alignment trench T0 can be formed by etching the upper protective layer 130 formed on the upper surface of the base chip 110 to a predetermined depth in the edge area EA.

The plurality of trenches T0 and T1 can be positioned on the same level as each other. In more detail, the lower level of the first trench T1 and the lower level of the second trench T2 can be located on substantially the same level as the lower level of the alignment trench T0.

The plurality of trenches T0, T1, and T2 can be formed to have cross sections of various shapes by variously designing photoresist pattern masks (PRP masks). For example, the alignment trench T0, the first trench T1, and the second trench T2 can be formed such that the shape of a cross section cut in directions (X, Y directions) orthogonal to the direction (Z direction) in which a plurality of semiconductor chips are stacked has a square, rectangular, or cross shape, among other types of shapes.

Connection bumps 103 can be disposed below the base chip 100. The connection bumps 103 can be electrically connected to the plurality of semiconductor chips 200, 300, and 400 through the through-electrode 120. The connection bumps 103 can include, for example, tin (Sn) or an alloy containing tin (Sn) (e.g., Sn—Ag—Cu). In some implementations, the connection bumps 103 have a combination of a metal pillar and a solder ball. The connection bumps 103 can be electrically connected to external devices such as a module substrate and a system board. The base chip 110 can have a width greater than a width of each of the plurality of semiconductor chips 200, 300, and 400 in a horizontal direction (a direction parallel to the upper surface US) (e.g., an X and/or a Y direction). At least portions of the connection bumps 103 and at least portions of the lower pads 101 can be disposed at positions that do not overlap with the plurality of semiconductor chips 200, 300, and 400 in the vertical direction (Z direction).

The first semiconductor chip 200 is disposed on the base chip 100, and can include a first semiconductor substrate 210, a first back protective layer 230, first front pads 201 disposed on the first front surface FS1, first back pads 202 disposed on the first back surface BS1, a first device layer 240, and first through-vias 220 electrically connecting the first front pads 201 and the first back pads 202. The first semiconductor substrate 210, the first back protective layer 230, the first front pads 201, the first back pads 202, the first device layer 240, and the first through-vias 220 have the same or similar characteristics as corresponding elements of the base chip 100 described above, the base substrate 110, the upper protective layer 130, the upper pad 102, the lower pad 101, the device layer 140, and the through-electrodes 120, and thus, redundant descriptions thereof are omitted. The first semiconductor chip 200 can have a first front surface FS1 on which the first front pads 201 are disposed, a first back surface BS1 on which the first back pads 202 are disposed, and a first side surface 200S extending from the edge of the first front surface FS1 to the edge of the first back surface BS1.

The second semiconductor chip 300 can be disposed on the first semiconductor chip 200, and can include a second semiconductor substrate 310, a second back protective layer 330, second front pads 301 disposed on a second front surface FS2, second back pads 302 disposed on a second back surface BS2, a second device layer 340, and second through-vias 320 electrically connecting the second front pads 301 and the second back pads 302. The second semiconductor substrate 310, the second back protective layer 330, the second front pads 301, the second back pads 302, the second device layer 340, and the second through-vias 320 have the same or similar characteristics as corresponding elements of the base chip 100 described above, the base substrate 110, the upper protective layer 130, the upper pad 102 and the lower pad 101, the device layer 140, and the through-electrodes 120, and thus, duplicate descriptions thereof are omitted. Depending on the particular implementation, the second semiconductor chip 300 can be provided as a plurality of second semiconductor chips stacked in a vertical direction (Z direction) on the first semiconductor chip 200.

The plurality of second semiconductor chips 300 can have the second front surface FS2 on which the second front pads 301 are disposed, respectively, a second back surface BS2 on which the second back pads 302 are disposed, and a second side surface 300S extending from the edge of the second front surface FS2 to the edge of the second back surface BS2. The plurality of second semiconductor chips 300 can be electrically connected to each other through second through-vias 320 electrically connecting the second front pads 301 and the second back pads 302. Depending on the particular implementation, the number of the plurality of second semiconductor chips 300 can be 1 or 3 or more.

The third semiconductor chip 400 is disposed on the second semiconductor chip 300, and can include the third semiconductor substrate 401, the third front pads 402 disposed on the third front surface FS3, and the third device layer 440. The third semiconductor substrate 401, the third front pads 402, and the third device layer 440 have the same or similar characteristics as the corresponding elements of the above-described base chip 100, the base substrate 110, the lower pad 101, and the device layer 140, and thus, redundant descriptions are omitted. The third semiconductor chip 400 can have a third front surface FS3 on which the third front pads 402 are disposed, a third back surface BS3 opposite to the third front surface BS3, and a third side surface 400S (not illustrated) extending from the edge of the third front surface FS3 to the edge of the third back surface BS3. The third semiconductor chip 400 can be disposed on the uppermost side of the plurality of semiconductor chips 200, 300, and 400, and the third back surface BS3 can be exposed from the molding member 600. Also, the third semiconductor chip 400 can have a thickness greater than the thickness of the first semiconductor chip 200 and the thickness of each of the plurality of second semiconductor chips 300.

The bump structures 203, 303, and 403 can be disposed between the plurality of semiconductor chips 200, 300, and 400. For example, the bump structures 203, 303, and 403 can include first bump structures 203 disposed between the base chip 100 and the first front surface FS1 of the first semiconductor chip 200, second bump structures 303 disposed on the second front surface FS2 of each of the plurality of second semiconductor chips 300, and third bump structures 403 disposed between the third front surface FS3 of the third semiconductor chip 400 and the uppermost second semiconductor chip 300. The bump structures 203, 303, and 403 can electrically connect pads facing each other. The first bump structures 203 can electrically connect the upper pads 102 of the base chip 100 and the first front pads 201 of the first semiconductor chip 200. The second bump structures 303 can electrically connect the first back pads 202 of the first semiconductor chip 200, and the front pads 201, 301, 401 and the back pads 202 and 302 of the plurality of second semiconductor chips 300 of the lowermost second semiconductor chip 300. The third bump structures 403 can electrically connect the second back pads 302 of the uppermost second semiconductor chip 300 and the third front pads 402 of the third semiconductor chip 400. The bump structures 203, 303, and 403 can include, for example, tin (Sn), indium (In), bismuth (Bi), antimony (Sb), copper (Cu), silver (Ag), zinc (Zn), lead (Pb) and/or alloys thereof. Examples of the alloy can include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, and the like.

The adhesive layers 510, 520, and 530 can surround some bump structures (e.g., 203 and 303) disposed between the plurality of semiconductor chips 200, 300, and 400 from among the bump structures 203, 303, and 403, and can fix a plurality of semiconductor chips 200, 300, and 400 to the base chip 100. The adhesive layers 510, 520, and 530 can be respectively disposed on the second front surface FS2 of the plurality of second semiconductor chips 300 and the third front surface FS3 of the third semiconductor chip 400. The adhesive layers 510, 520, and 530 can include a first adhesive layer 510 surrounding the first bump structures 203 under the first semiconductor chip 200, a second adhesive layer 520 surrounding the second bump structures 303 under the second semiconductor chip 300, and a third adhesive layer 530 surrounding the third bump structures 350 under the third semiconductor chip 400.

The adhesive layers 510, 520, and 530 can be Non Conductive Films (NCFs), but are not limited thereto, and can include, for example, all types of polymer films capable of thermal compression bonding. The fillet layers 510, 520, and 530 can protrude further than side surfaces of the plurality of semiconductor chips 200, 300, and 400 to form protrusions. The protrusions of the fillet layers can contact molding members disposed on side surfaces of the plurality of semiconductor chips. Among the fillet layers 510, 520, and 530, the first fillet layer 510 can fill at least a portion of the first trench formed in the transistor area formed by the through-electrode 120, and a portion of the protrusion of the first fillet layer 510 can fill at least a portion of the second trench formed in the edge area. At this time, the inside of the second trench can be filled with not only the protrusion of the first fillet layer but also a portion of the molding member.

The molding member 600 can seal the plurality of semiconductor chips 200, 300, and 400 on the base chip 100. The molding member 600 can be formed to expose the back surface BS3 of the third semiconductor chip 400. Depending on some implementations, the molding member 600 can be formed to cover the back surface BS3 of the third semiconductor chip 400. The molding member 600 can be formed of, for example, an insulating material such as an Epoxy Mold Compound (EMC), but the material of the molding member 600 is not particularly limited. The molding member 600 can surround side surfaces of the plurality of semiconductor chips 200, 300, and 400. The molding member 600 is formed on the base chip 100, and can directly contact the side surfaces 200S, 300S, and 300S of the plurality of semiconductor chips 200, 300, and 400 and the side surfaces 510S of the adhesive layers 510. Depending on the particular implementation, a heat dissipation structure (not illustrated) can be disposed above the molding member 600. The heat dissipation structure (not illustrated) controls warpage of the semiconductor package 1000, and heat generated from the plurality of semiconductor chips 200, 300, and 400 can be released externally.

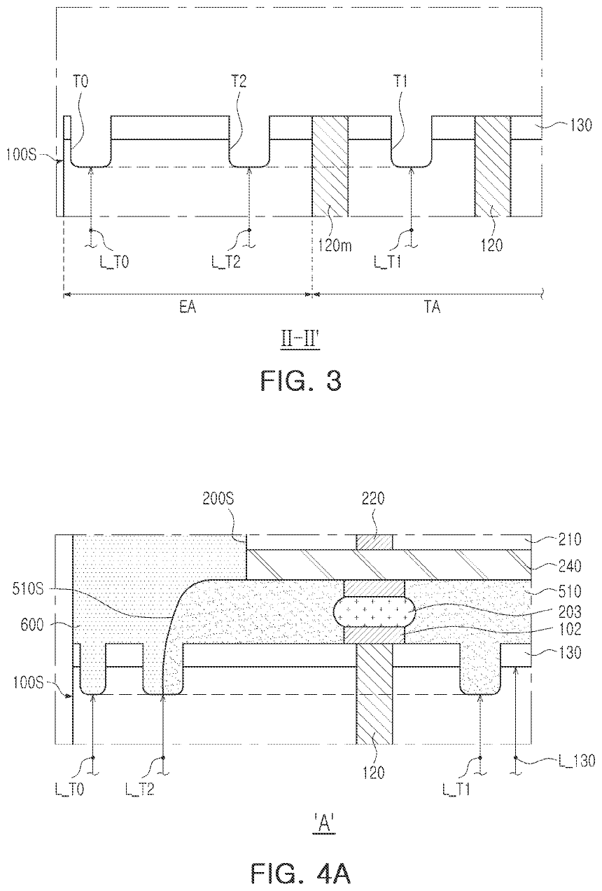

FIG. 3 is a partially enlarged view illustrating a region ‘A’ in FIG. 1.

Referring to FIG. 3, the alignment trench T0 can be formed in the edge area EA and can be formed adjacent to the side surface 100S of the base substrate 110 (or the side surface of the upper protective layer 130). The second trench T2 can be formed in the edge area EA and can be formed along an edge of the transistor area TA. The first trench T1 can be formed between adjacent through-electrodes 120 in the transistor area TA.

The lower level L_T0 of the alignment trench, the lower level L_T1 of the first trench, and the lower level L_T2 of the second trench can be positioned on substantially the same level as each other. For example, the alignment trench T0, the first trench T1, and the second trench T2 can be formed together.

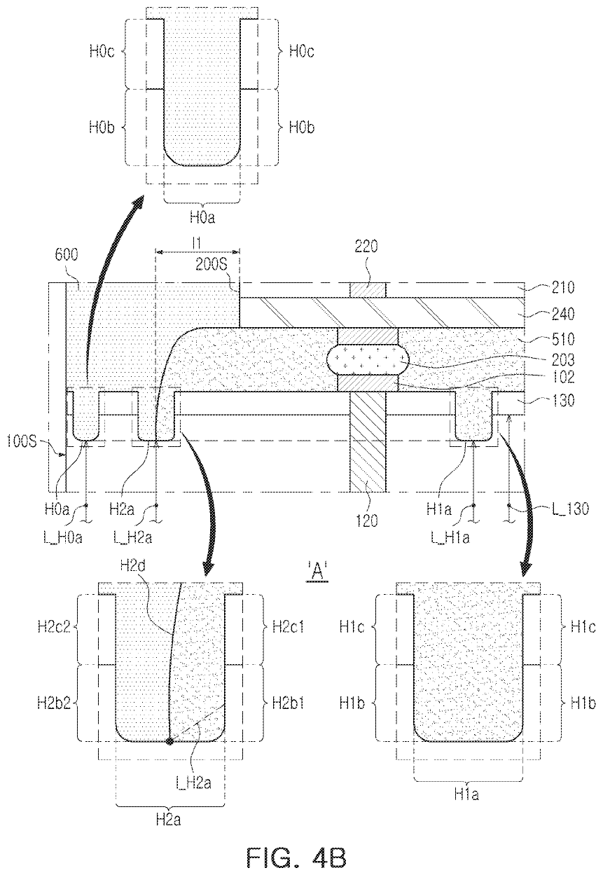

FIG. 4A is a partially enlarged view illustrating the ‘A’ region of FIG. 1.

Referring to FIG. 4A, the lower level L_T0 of the alignment trench, the lower level L_T1 of the first trench, and the lower level L_T2 of the second trench can be formed at a level lower than the lower level L_130 of the upper protective layer. For example, the alignment trench T0, the first trench T1, and the second trench T2 are etched thicker than the thickness of the upper protective layer 130, and thus, the distances of the lower surfaces of the alignment trench T0, the first trench T1, and the second trench T2 from the lower surface LS of the base chip 100 can be formed to be closer than the distance between the upper protective layer 130 and the lower surface LS of the base chip 100. The thicknesses of the alignment trench T0, the first trench T1, and the second trench T2 can be formed to have a depth of several μm or more from the upper surface of the upper protective layer 130, and in detail, can be formed to a depth of 1 μm or more. At this time, the lower level L_T0 of the alignment trench, the lower level L_T1 of the first trench, and the lower level L_T2 of the second trench can be formed to be positioned on substantially the same level as each other.

FIG. 4B is a partially enlarged view illustrating the ‘A’ region of FIG. 1.

Referring to FIG. 4B, the alignment trench T0, the first trench T1, and the second trench T2 are etched to a thickness greater than a thickness of the upper protective layer 130, and the molding member 600 and/or the first fillet layer 510 fills the inside of the trenches.

A portion of the first fillet layer 510 can fill at least a portion of the first trench T1. At the upper portion of the first trench T1, a portion of the first fillet layer 510 can contact the upper protective layer 130 to form a heterogeneous interface H1c between the first fillet layer 510 and the upper protective layer 130. At the lower portion of the first trench T1, the remaining portion of the first fillet layer 510 can contact the base substrate 110 to form a heterogeneous interface H1b between the first fillet layer 510 and the base substrate 110. On the lower surface of the first trench T1, the remaining portion of the first fillet layer 510 can contact the base substrate 110 to form a heterogeneous interface H1a (or a “first heterogeneous interface H1a”) between the first fillet layer 510 and the base substrate 110. The first heterogeneous interface H1a can have a lowest level among heterogeneous interfaces formed inside the first trench T1.

The second trench T2 can be formed at a predetermined distance 11 from the side surface 200S of the first semiconductor chip 200. For example, the central portion of the second trench T2 can be formed 1 nm to several thousand μm away from the side surface 200S of the first semiconductor chip 200, in detail, 10 nm to 1000 μm away therefrom.

The side surface 510S of the protrusion of the first fillet layer can contact the molding member 600 to form a heterogeneous interface H2d. A portion of the protrusion of the first fillet layer 510S and a portion of the molding member 600 can fill at least a portion of the second trench T2. On one side surface of the upper portion of the second trench T2, a portion of the first fillet layer 510 can be in contact with the upper protective layer 130 to form a heterogeneous interface H2c1 between the first fillet layer 510 and the upper protective layer 130. On one side surface of the lower portion of the second trench T2, the remaining portion of the first fillet layer 510 can contact the base substrate 110 to form a heterogeneous interface H2b1 between the first fillet layer 510 and the base substrate 110. On the other side surface of the upper portion of the second trench T2, a portion of the molding member 600 can contact the upper protective layer 130 to form a heterogeneous interface H2c2 between the molding member 600 and the upper protective layer 130. On one side surface of the lower portion of the second trench T2, a portion of the first fillet layer 510 can contact the base substrate 110 to form a heterogeneous interface H2b1 between the first fillet layer 510 and the base substrate 110. On the other side surface of the lower portion of the second trench T2, the remaining portion of the molding member 600 can contact the base substrate 110 to form a heterogeneous interface H2b2 between the molding member 600 and the base substrate 110. On the lower surface of the second trench T2, a portion of the first fillet layer 510 and a portion of the molding member 600 can contact the base substrate 110, to form a heterogeneous interface H2a (or “second heterogeneous interface H2a”) between the first fillet layer 510, the molding member 600 and the base substrates 110, and can form a triplet 1_H2a extending in the Y direction. The second heterogeneous interface H2a can have a lowest level among heterogeneous interfaces formed inside the second trench T2.

A portion of the molding member 600 can fill at least a portion of the inside of the alignment trench T0. On the upper side of the alignment trench T0, a portion of the molding member 600 contacts the upper protective layer 130 to form a heterogeneous interface H0c between the molding member 600 and the upper protective layer 130. On the lower side of the alignment trench T0, a remaining portion of the molding member 600 can contact the base substrate 110 to form a heterogeneous interface H0b between the molding member 600 and the base substrate 110. On the lower surface of the alignment trench T0, a remaining portion of the molding member 600 can contact the base substrate 110 to form a heterogeneous interface H0a (or “third heterogeneous interface (H0a)”) between the molding member 600 and the base substrate 110. The third heterogeneous interface H0a can have a lowest level among heterogeneous interfaces formed inside the alignment trench T0.

As the lower level of the alignment trench L_T0, the lower level of the first trench L_T1, and the lower level of the second trench L_T2 are located at a lower level than the lower level of the upper protective layer L_130, the area of the heterogeneous interface formed inside the alignment trench T0, the first trench T1, and the second trench T2 is improved, and thus, a semiconductor package having excellent reliability can be provided. For example, the lower level L_T0 of the alignment trench, the lower level L_T1 of the first trench, and the lower level L_T2 of the second trench are located at a lower level than the lower level L_130 of the upper protective layer, and thus, the areas of a heterogeneous interface H0b formed on the lower side of the alignment trench T0, a heterogeneous interface H1b formed on the lower side of the first trench T1, and heterogeneous interfaces H2b1 and H2b2 formed on the lower sides of the second trench T2 can be improved.

On the other hand, the lower level L_H0a of the third heterogeneous interface H0a formed on the lower surface of the alignment trench T0, the lower level L_H1a of the first heterogeneous interface H1a formed on the lower surface of the first trench T1, and the lower level L_H2a of the second heterogeneous interface H2a formed on the lower surface of the second trench T2 can be formed and positioned on substantially the same level as each other.

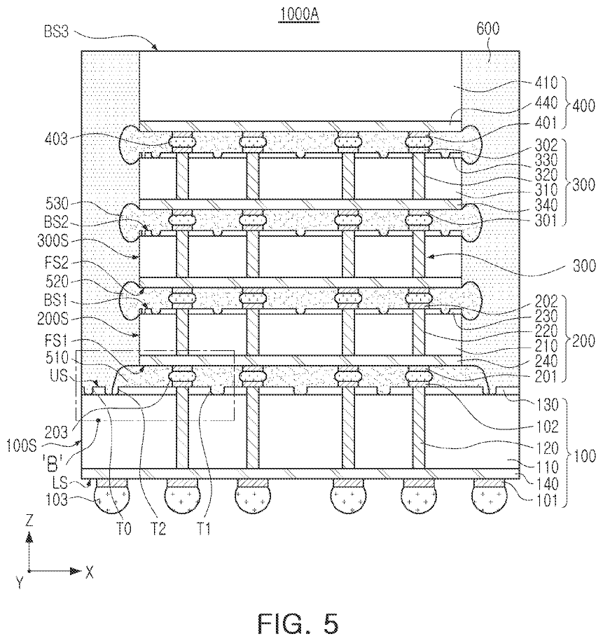

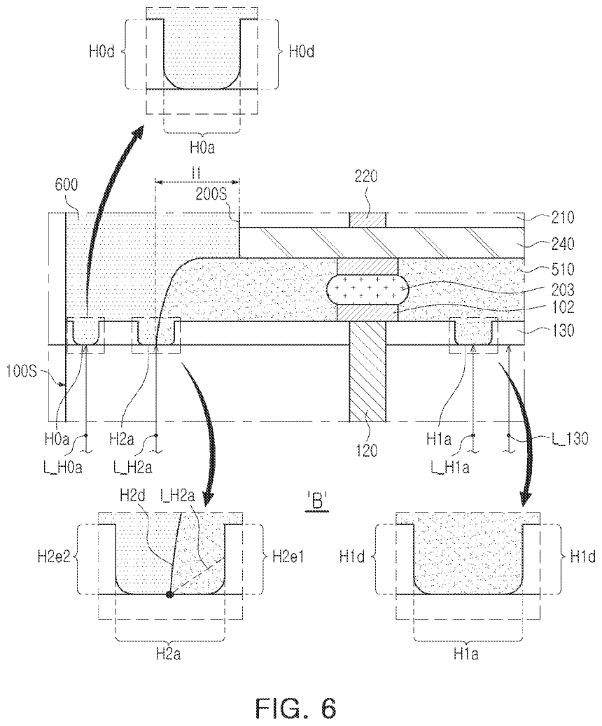

FIG. 5 is a cross-sectional view illustrating a semiconductor package 1000A according to some implementations, and FIG. 6 is a partially enlarged view illustrating a region ‘B’ of FIG. 5.

Referring to FIGS. 5 and 6, in a semiconductor package 1000A of a modified example, the lower level L_T0 of the alignment trench, the lower level L_T1 of the first trench, and the lower level L_T2 of the second trench can be positioned on substantially the same level as the lower level L_130 of the upper protective layer 130. For example, the alignment trench T0, the first trench T1, and the second trench T2 are etched to have substantially the same thickness as the upper protective layer 130, such that the distances of the alignment trench T0, the first trench T1, and the second trench T2 from the lower surface LS of the base chip 100 can be substantially equal to the distance between the upper protective layer 130 and the lower surface LS of the base chip 100.

A portion of the first fillet layer 510 can fill at least a portion of the first trench T1. On the side of the first trench T1, a portion of the first fillet layer 510 can contact the upper protective layer 130 to form a heterogeneous interface H1d between the first fillet layer 510 and the upper protective layer 130. On the lower surface of the first trench T1, a remaining portion of the first fillet layer 510 can contact the base substrate 110 to form a heterogeneous interface H1a (or a “first heterogeneous interface H1a”) between the first fillet layer 510 and the base substrate 110. The first heterogeneous interface H1a can have a lowest level among heterogeneous interfaces formed inside the first trench T1.

The second trench T2 can be formed at a predetermined distance 11 from the side surface 200S of the first semiconductor chip 200. For example, the central portion of the second trench T2 can be formed 1 nm to several thousand μm away from the side surface 200S of the first semiconductor chip 200, in detail, formed 10 nm to 1000 μm away therefrom.

The side surface 510S of the protrusion of the first fillet layer can contact the molding member 600 to form a heterogeneous interface H2d, and a portion of the protrusion of the first fillet layer 510 and a portion of the molding member 600 can fill at least a portion of the second trench T2. On one side of the second trench T2, a portion of the first fillet layer 510 can contact the upper protective layer 130 to form a heterogeneous interface H2e1 between the first fillet layer 510 and the upper protective layer 130. On the other side of the second trench T2, a portion of the molding member 600 can contact the upper protective layer 130 to form a heterogeneous interface H2e2 between the molding member 600 and the upper protective layer 130. On the lower surface of the second trench T2, a portion of the first fillet layer 510 and a portion of the molding member 600 can contact the base substrate 110, to form a heterogeneous interface H2a (or “second heterogeneous interface H2a”) between the first fillet layer 510, the molding member 600 and the base substrates 110 and to form a triplet 1_H2a extending in the Y direction. The second heterogeneous interface H2a can have a lowest level among heterogeneous interfaces formed inside the second trench T2.

A portion of the molding member 600 can fill at least a portion of the inside of the alignment trench T0. On the side of the alignment trench T0, a portion of the molding member 600 can contact the upper protective layer 130 to form a heterogeneous interface H0d between the molding member 600 and the upper protective layer 130. On the lower surface of the alignment trench T0, a remaining portion of the molding member 600 can contact the base substrate 110 to form a heterogeneous interface H0a (or “third heterogeneous interface H0a”) between the molding member 600 and the base substrate 110. The third heterogeneous interface H0a can have a lowest level among heterogeneous interfaces formed inside the alignment trench T0.

On the other hand, the lower level L_H0a of the third heterogeneous interface H0a formed on the lower surface of the alignment trench T0, the lower level L_H1a of the first heterogeneous interface H1a formed on the lower surface of the first trench T1, and the lower level L_H2a of the second heterogeneous interface H2a formed on the lower surface of the second trench T2 can be positioned on substantially the same level as each other.

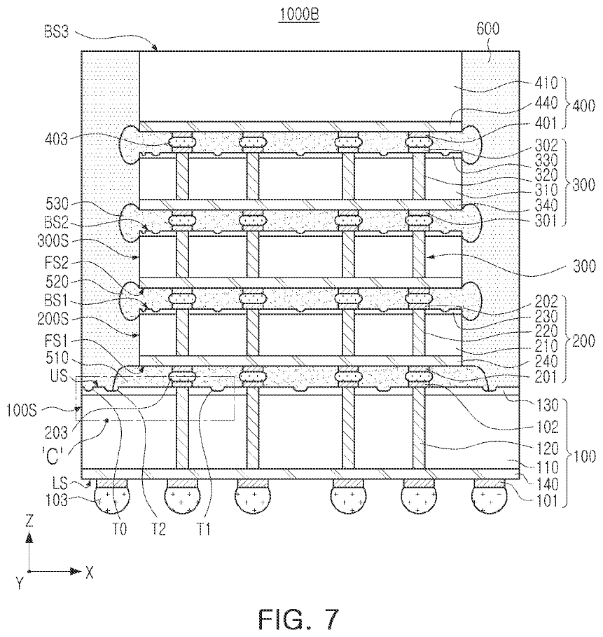

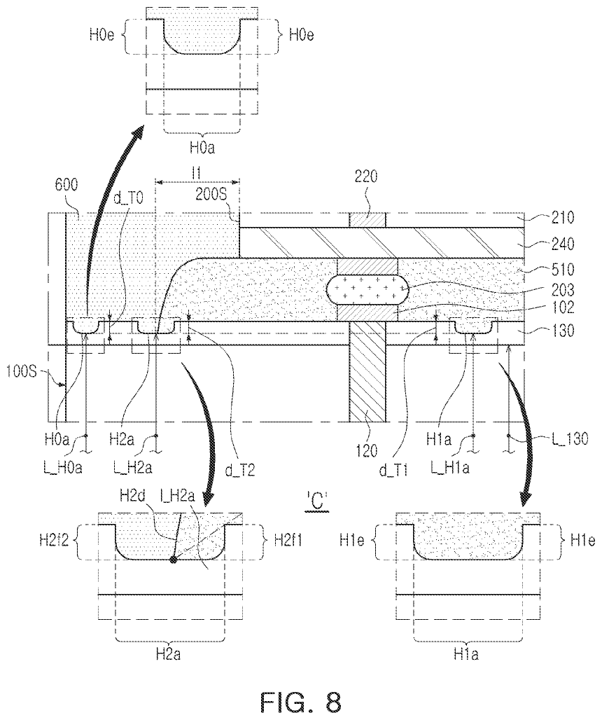

FIG. 7 is a cross-sectional view illustrating a semiconductor package 1000B according to some implementations, and FIG. 8 is a partially enlarged view illustrating a ‘C’ region of FIG. 7.

Referring to FIGS. 7 and 8, in the semiconductor package 1000B of a modified example, the lower level L_T0 of the alignment trench, the lower level L_T1 of the first trench, and the lower level L_T2 of the second trench can be formed at a level higher than the lower level L_130 of the upper protective layer. For example, the alignment trench T0, the first trench T1, and the second trench T2 are etched to a thickness less than a thickness of the upper protective layer 130, such that the distances of the lower surfaces of the alignment trench T0, the first trench T1, and the second trench T2 from the lower surface LS of the base chip 100 can be greater than the distance between the upper protective layer 130 and the lower surface LS of the base chip 100. The thickness d_T0 of the alignment trench, the thickness d_T1 of the first trench, and the thickness d_T2 of the second trench can be formed to have a depth of 10 nm to several μm from the upper surface of the upper protective layer 130, in detail, a depth of 10 nm to 1 μm. In this case, the thickness d_T0 of the alignment trench, the thickness d_T1 of the first trench, and the thickness d_T2 of the second trench can be formed to have substantially the same thickness.

The lower level L_T0 of the alignment trench, the lower level L_T1 of the first trench, and the lower level L_T2 of the second trench can be formed on substantially the same level as each other.

A portion of the first fillet layer 510 can fill at least a portion of the first trench T1. On the side of the first trench T1, a portion of the first fillet layer 510 can contact the upper protective layer 130 to form a heterogeneous interface H1e between the first fillet layer 510 and the upper protective layer 130. On the lower surface of the first trench T1, a remaining portion of the first fillet layer 510 can be in contact with the base substrate 110, to form a heterogeneous interface H1a (or “first heterogeneous interface H1a”) between the first fillet layer 510 and the base substrate 110. The first heterogeneous interface H1a can have a lowest level among heterogeneous interfaces formed inside the first trench T1.

The second trench T2 can be formed at a predetermined distance 11 from the side surface 200S of the first semiconductor chip 200. For example, the central portion of the second trench T2 can be formed 1 nm to several thousand μm away from the side surface 200S of the first semiconductor chip 200, in detail, formed 10 nm to 1000 μm away therefrom.

The side surface 510S of the protrusion of the first fillet layer can contact the molding member 600 to form a heterogeneous interface H2d, and a portion of the protrusion of the first fillet layer 510 and a portion of the molding member 600 can fill at least a portion of the second trench T2. On one side of the second trench T2, a portion of the first fillet layer 510 can contact the upper protective layer 130 to form a heterogeneous interface H2f1 between the first fillet layer 510 and the upper protective layer 130. On the other side of the second trench T2, a portion of the molding member 600 can contact the upper protective layer 130 to form a heterogeneous interface H2f2 between the molding member 600 and the upper protective layer 130. On the lower surface of the second trench T2, a portion of the first fillet layer 510 and a portion of the molding member 600 can contact the base substrate 110 to form a heterogeneous interface H2a (or “second heterogeneous interface H2a”) between the first fillet layer 510, the molding member 600 and the base substrates 110, and to form a triplet 1_H2a extending in the Y direction. The second heterogeneous interface H2a can have a lowest level among heterogeneous interfaces formed inside the second trench T2.

A portion of the molding member 600 can fill at least a portion of the inside of the alignment trench T0. On the side of the alignment trench T0, a portion of the molding member 600 can contact the upper protective layer 130 to form a heterogeneous interface H0e between the molding member 600 and the upper protective layer 130. On the lower surface of the alignment trench T0, a remaining portion of the molding member 600 can contact the base substrate 110 to form a heterogeneous interface H0a (or “third heterogeneous interface H0a”) between the molding member 600 and the base substrate 110. The third heterogeneous interface H0a can have a lowest level among heterogeneous interfaces formed inside the alignment trench T0.

On the other hand, the lower level L_H0a of the third heterogeneous interface H0a formed on the lower surface of the alignment trench T0, the lower level L_H1a of the first heterogeneous interface H1a formed on the lower surface of the first trench T1, and the lower level L_H2a of the second heterogeneous interface H2a formed on the lower surface of the second trench T2 can be positioned on substantially the same level as each other.

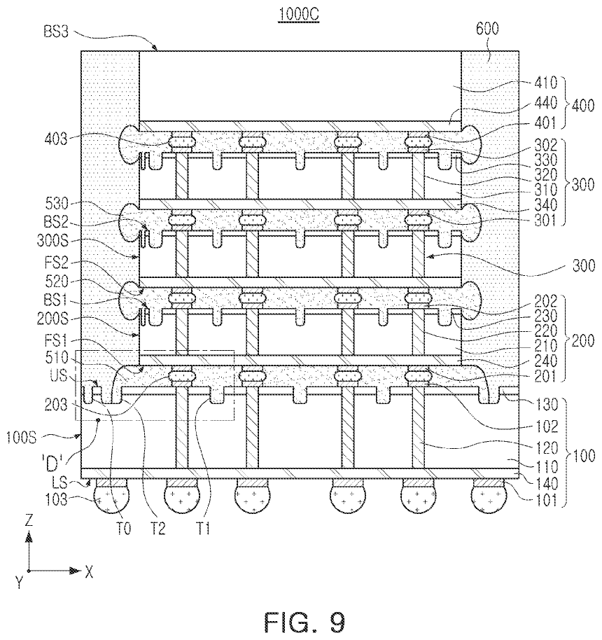

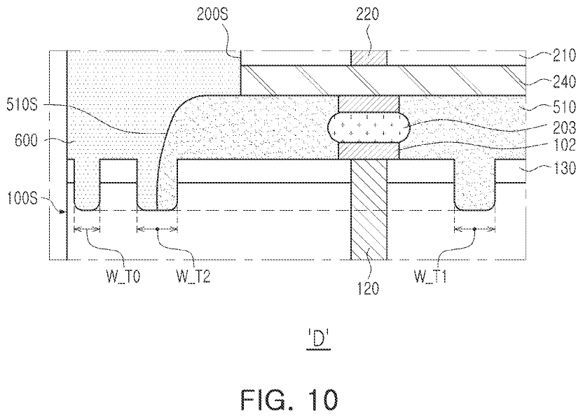

FIG. 9 is a cross-sectional view illustrating a semiconductor package 1000B according to some implementations, and FIG. 10 is a partially enlarged view illustrating a ‘D’ region of FIG. 9.

Referring to FIGS. 9 and 10, in the semiconductor package 1000B of a modified example, a width W_T2 of the second trench can be greater than a width W_T0 of the alignment trench and a width W_T1 of the first trench. As the width of the second trench W_T2 is greater than the width of the first trench W_T1, the area of the heterogeneous interface formed by the contact of dissimilar materials on the lower surface of the second trench T2 can be improved, and a semiconductor package having excellent reliability can be provided. The width of the second trench W_T2 can be formed as a width of 10 nm to several tens of μm, and in detail, can be formed as a width of 10 nm to 100 μm. For example, portions of the first fillet layer 510 and the molding member 600 can contact the base substrate 110 on the lower surface of the second trench T2 to form a heterogeneous interface H2a having an increased area.

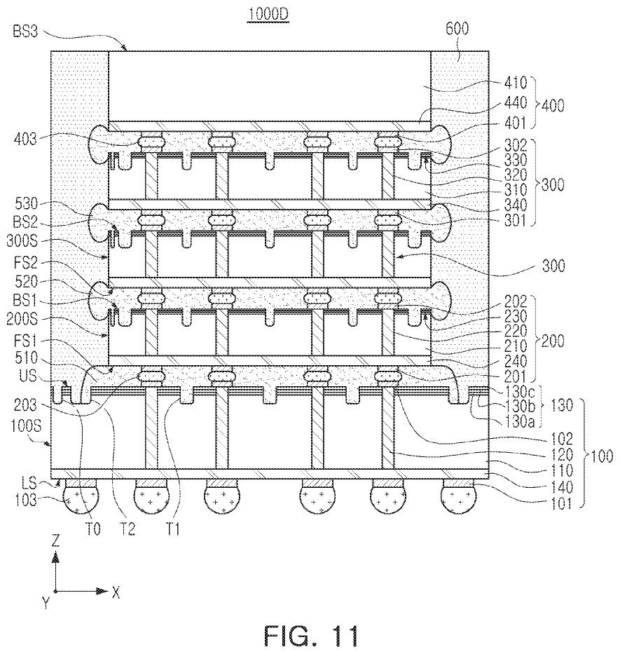

FIG. 11 is a cross-sectional view illustrating a semiconductor package 1000C according to some implementations.

Referring to FIG. 11, in the semiconductor package 1000C of a modified example, the upper protective layer 130 can be formed as a plurality of layers on the upper surface of the base substrate 110. For example, the upper protective layer 130 can be formed of a plurality of layers in which a first protective layer 130a, a second protective layer 130b, and a third protective layer 130c are sequentially stacked on the upper surface of the base substrate 110. For example, the first protective layer 130a, the second protective layer 130b, and the third protective layer 130c can be a silicon oxide film, a silicon nitride film, and a silicon oxide film, respectively, but are not limited thereto.

The lower level L_T0 of the alignment trench, the lower level L_T1 of the first trench, and the lower level L_T2 of the second trench can be formed on substantially the same level as each other. For example, the alignment trench T0, the first trench T1, and the second trench T2 can be formed simultaneously with each other.

The lower level L_T0 of the alignment trench, the lower level L_T1 of the first trench, and the lower level L_T2 of the second trench can be formed at a level lower than the lower level of the first protective layer 130a.

The lower levels L_T0, L_T1, and L_T2 of the plurality of trenches can be formed at the same level as the lower level of the first protective layer 130a.

The lower levels L_T0, L_T1, and L_T2 of the plurality of trenches can be formed at a level between the lower level of the first protective layer 130a and the upper level of the third protective layer 130c. For example, the lower levels L_T0, L_T1, and L_T2 of the plurality of trenches can be formed at a level between the lower level of the second protective layer 130b and the lower level of the first protective layer 130a. The lower levels L_T0, L_T1, and L_T2 of the plurality of trenches can be formed at the same level as the lower level of the second protective layer 130b. The lower levels L_T0, L_T1, and L_T2 of the plurality of trenches can be formed at a level between the lower level of the third protective layer 130c and the lower level of the second protective layer 130b. The lower levels L_T0, L_T1, and L_T2 of the plurality of trenches can be formed at the same level as the lower level of the third protective layer 130b. The lower levels L_T0, L_T1, and L_T2 of the plurality of trenches can be formed at a level between the upper level of the third protective layer 130c and the lower level of the third protective layer 130c.

The lower level of the second protective layer 130b can be at the same level as the upper level of the first protective layer 130a. The lower level of the third protective layer 130c can be at the same level as the upper level of the second protective layer 130b.

A portion of the first fillet layer 510 and/or a portion of the molding member 600 can fill at least portions within the alignment trench T0, the first trench T1, and the second trench T2. In this case, a portion of the first fillet layer 510 and/or a portion of the molding member 600 can contact the first protective layer 130a and/or the second protective layer 130b and/or the third protective layer 130c and/or the base substrate 110 depending on the depth at which the trenches are etched, thereby forming various heterogeneous interfaces.

A width W_T2 of the second trench can be greater than a width W_T0 of the alignment trench and a width W_T1 of the first trench. In this case, the width of the second trench W_T2 can be formed as a width of 10 nm to several tens of μm, and in detail, can be formed as a width of 10 nm to 100 μm. On the other hand, the width W_T2 of the second trench can be formed to be the same as the width W_T0 of the alignment trench and the width W_T1 of the first trench.

FIGS. 12A to 12J are cross-sectional views schematically illustrating a process of manufacturing a semiconductor package 1000B according to some implementations.

Referring to FIG. 12A, a base substrate 110, through-electrodes 120, device layers 140, lower pads 101, and connection bumps 103 can be prepared to provide a base chip 100, and for the back-grinding process of FIG. 12B, can be temporarily supported on a carrier CR through adhesion with a tape TP.

Referring to FIG. 12B, the base substrate 110 can be ground to the same level as the through-electrodes 120 through a back-grinding process (not illustrated), and a portion of the through-electrodes 120 can be formed by protruding onto the base substrate 110 through a subsequent etch-back process. The upper protective layer 130 can be formed on the upper surface of the base substrate 110 and the upper surface of the through-electrodes 120 that partially protrude. The upper protective layer 130 can be formed by a deposition process or the like. The upper protective layer 130 can be formed of an insulating layer such as a silicon oxide film, a silicon nitride film, or a silicon oxynitride film, but the material of the upper protective layer 130 is not limited to the above materials. For example, the upper protective layer 130 can be formed of an insulating material such as a Photo-Imageable Dielectric (PID) material, or can be formed of a polymer such as Polyimide (PI) or Photosensitive polyimide (PSPI).

On the other hand, the upper protective layer 130 can be formed of a plurality of layers in which the first protective layer 130a, the second protective layer 130b, and the third protective layer 130c are sequentially stacked on the upper surface of the base substrate 110 and the upper surface of the through-electrodes 120 partially protruding. For example, the plurality of layers can be formed of a layer in which a silicon oxide layer, a silicon nitride layer, and a silicon oxide layer are sequentially stacked. In this case, respective materials of the plurality of layers are not limited to the above materials.

In addition, although not illustrated in the drawing, a protective layer (“lower protective layer”) can be further formed on the lower surface of the device layer 140.

Referring to FIG. 12C, a photoresist is applied on the upper protective layer 130 and is subjected to spin-coating, thereby forming a photoresist coating C having a predetermined thickness. The photoresist can be composed of a solvent, a resin, and a photoactive compound (PAC), but is not limited thereto.

Referring to FIG. 12D, a photomask M having a pattern drawn thereon can be disposed at a predetermined distance from the photoresist coating C formed on the upper surface of the upper protective layer 130. The photomask M can be designed to have various patterns to adjust the shape and width of the plurality of trenches T0, T1, and T2.

Referring to FIG. 12E, an exposure process can be performed in a state in which the photomask M on which the pattern is drawn is spaced apart from the photoresist coating C by a predetermined distance, and a developing process can be performed after an exposure process is performed, to solidify the photosensitive material. The alignment trench T0 can be formed on the base substrate 110 (or the upper protective layer 130) by etching. Etching can be performed by dry etching, but is not limited thereto.

The first trench T1 and the second trench T2 can be formed together with the alignment trench T0. In this case, the lower level L_T2 of the first trench L_T1 and the second trench can be formed on substantially the same level as the lower level of the alignment trench L_T0. Also, the lower level L_T0 of the alignment trench, the lower level L_T1 of the first trench, and the lower level L_T2 of the second trench can be formed at a lower level than the lower level L_130 of the upper protective layer 130, but the subject matter of the present disclosure is not limited thereto. For example, by controlling the depth to be etched, the lower level L_T0 of the alignment trench, the lower level L_T1 of the first trench, and the lower level L_T2 of the second trench can be formed at the same level as the lower level of the upper protective layer 130, or can be formed at a level higher than the lower level of the upper protective layer 130.

The width W_T2 of the second trench can be greater than the width W_T0 of the alignment trench and the width W_T1 of the first trench, but other widths are also possible. For example, by designing the pattern of the photomask M in various manners, the width W_T2 of the second trench can be equal to or less than the width W_T0 of the alignment trench and the width W_T1 of the first trench.

In some implementations, the first trench T1 and the second trench T2 are formed together with the alignment trench T0 functioning as an alignment key without going through separate photoresist application, coating, exposure, development, and etching processes. In some implementations, a semiconductor package having improved process efficiency and reliability can be provided.

Referring to FIG. 12E, both the alignment trench T0 and the second trench T0 are illustrated, but are not limited thereto. For example, referring to FIG. 13A, the width of the second trench can be greater than the width of the alignment trench. Referring to FIG. 13C, the second trench can extend in the X or Y longitudinal direction and be formed of a plurality of layers. In this case, the alignment trench T0 does not appear in the cross-sectional view of the semiconductor package.

Referring to FIG. 12F, the photoresist coating C material remaining without being etched can be removed. Removal can proceed after a dry etching process. Thereafter, the through-electrodes 120 that partially protrude, and the upper protective layer 130 formed on the upper surfaces of the partially protruding through-electrodes 120, can be planarized by a planarization process. Through the planarization process, the protruding through-electrodes 120 and the upper protective layer 130 formed on the upper surface of the through-electrodes 120 can be located on the same plane as the upper surface of the upper protective layer 130 formed on the upper surface of the base substrate 110. The planarization process can be performed, for example, by a chemical mechanical polishing (CMP) process.

Referring to FIG. 12G, the upper pad 120 can be disposed on the upper surface US of the base chip 100 (or on an upper portion of the upper protective layer 130), and can be disposed to cover the through-electrodes 120 exposed on the base chip 100. The upper pad 102 can include, for example, at least one of aluminum (Al), copper (Cu), nickel (Ni), tungsten (W), platinum (Pt), and gold (Au), but other materials are also possible.

Referring to FIG. 12H, the first semiconductor chip 200 can be stacked vertically (Z direction) on the base chip 100. Lamination can be performed by a thermal compression bonding (TCB) method, and the first semiconductor chip 200 can be adhered to the base chip 100 by the first fillet layer 510. The first semiconductor chip 200 can be stacked such that the first back pads 202 of the first semiconductor chip 200 contact the upper pad 120 of the base chip 100.

Referring to FIG. 12I, a thermal compression process can be performed between the base chip 100 and the first semiconductor chip 200. The first fillet layer 510 is in an uncured state in the thermal compression process, and a portion of the first fillet layer 510 can fill at least partially in the first trench T1 and the second trench T2. In this case, the first fillet layer 510 is in contact with the upper protective layer 130 or the base substrate 110 inside the first trench T1 and the second trench T2, thereby forming a heterogeneous interface.

Referring to FIG. 12J, a plurality of semiconductor chips 300 and 400 can be vertically stacked on the first semiconductor chip 200. The molding member 600 can seal the plurality of semiconductor chips 200, 300, and 400 on the base chip 100. The molding member 600 can be formed to expose the back surface BS3 of the third semiconductor chip 400. The molding member 600 is formed on the base chip 100, and can directly contact respective side surfaces 200S, 300S, and 300S of the plurality of semiconductor chips 200, 300, and 400 and the side surfaces 510S of the adhesive layers 510. A portion of the molding member 600 can fill at least a portion of the inside of the second trench T2. In this case, a heterogeneous interface between the first fillet layer 510, the molding member 600, and the upper protective layer 130 can be formed at the side of the second trench T2, and a heterogeneous interface between the first fillet layer 510, the molding member 600, and the base substrate 130 can be formed below the second trench T2.

When the plurality of semiconductor chips 200, 300, and 400 are sealed on the base chip 100 by the molding member 600, the tape TP and the carrier CR can be detached.

FIGS. 13A to 13C are cross-sectional views taken along line III-III′ in FIG. 12E.

FIGS. 13A to 13C illustrate that the second trench T2 among the plurality of trenches has various shapes, and the shape can be determined by designing the photomask of FIG. 12E in various patterns.

Referring to FIG. 13A, the second trench T2 can be formed to have a cross shape in the edge area EA. The width W_T2 of the second trench can be formed to have a greater size than the width W_T1 of the first trench.

Referring to FIG. 13B, the second trench T2 can be formed to extend in the X or Y longitudinal direction from the edge area EA. The second trench T2 can be formed to have the same length as the length of the X or Y length of the transistor area TA, but other lengths are also possible. For example, the second trench T2 can be formed to have a length shorter than the length of the transistor area TA in the Y longitudinal direction.

Referring to FIG. 13C, the second trench T2 extends in the longitudinal direction of X or Y in the edge area EA and can be formed of at least one layer.

Referring to FIGS. 13A to 13C, the sum of the internal volumes of the second trenches can be greater than the sum of the internal volumes of the first trenches.

As set forth above, according to some implementations, a semiconductor package having improved process efficiency is provided by forming a trench when an alignment key is formed without a separate patterning process in terms of process.

In addition, in terms of structure, a semiconductor package having improved reliability can be provided by differentially adjusting the etched depth or width of the trench formed in the transistor area and the trench formed in the region surrounding the transistor area.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While some implementations have been illustrated and described above, it will be apparent to those skilled in the art that modifications and variations could be made without departing from the scope of the present inventive concept as defined by the appended claims.

What is claimed is:

1. A semiconductor package comprising:
a base chip;
a first semiconductor chip on the base chip; and
a first fillet layer between the base chip and the first semiconductor chip,
wherein the base chip includes
a base substrate,
a plurality of through-electrodes penetrating through the base substrate, an upper protective layer surrounding the plurality of through-electrodes and covering an upper surface of the base substrate, and
a plurality of trenches vertically penetrating the upper protective layer,
wherein the plurality of through-electrodes form a transistor area on the base substrate, and
wherein the plurality of trenches include first trenches disposed between adjacent through-electrodes in the transistor area and second trenches disposed in an outer side portion of the transistor area.

2. The semiconductor package of claim 1, wherein the plurality of trenches further include an alignment trench horizontally spaced apart from the transistor area by a predetermined distance.

3. The semiconductor package of claim 2, wherein lower levels of the alignment trench, the first trenches, and the second trenches are at substantially the same level.

4. The semiconductor package of claim 1, wherein lower levels of the plurality of trenches are disposed higher than a lower level of the protective layer.

5. The semiconductor package of claim 4, wherein each trench of the plurality of trenches has a depth of between 10 nm to 1 μm.

6. The semiconductor package of claim 1, wherein lower levels of the plurality of trenches are disposed lower than a lower level of the protective layer.

7. The semiconductor package of claim 6, wherein each trench of the plurality of trenches has a depth of 1 μm or more.

8. The semiconductor package of claim 1, wherein each second trench has a width different from a width of each first trench.

9. The semiconductor package of claim 1, wherein each second trench has a width greater than a width of each first trench.

10. The semiconductor package of claim 9, wherein each first trench has a width of 10 μm to 100 μm.

11. The semiconductor package of claim 1, wherein each trench of the plurality of trenches has a width greater than its depth.

12. The semiconductor package of claim 1, wherein lower levels of the second trenches are disposed lower than a lower level of the upper protective layer,
a portion of the first fillet layer fills at least a portion of insides of the first trenches, contacts the base substrate and forms a first heterogeneous interface, and
the semiconductor package further includes a molding member disposed on the base chip and surrounding a side surface of the first fillet layer and a side surface of the first semiconductor chip.

13. The semiconductor package of claim 12, wherein portions of the first fillet layer and the molding member fill at least a portion of insides of the second trenches, contact the base substrate, and form a second heterogeneous interface.

14. A semiconductor package comprising:
a base chip;
a first semiconductor chip on the base chip; and
a first fillet layer between the base chip and the first semiconductor chip,
wherein the base chip includes
a base substrate,
a plurality of through-electrodes penetrating through the base substrate,
an upper protective layer surrounding the plurality of through-electrodes and covering an upper surface of the base substrate, and
a plurality of trenches vertically penetrating the upper protective layer,
wherein the plurality of through-electrodes form a transistor area on the base substrate, and
wherein the plurality of trenches includes
an alignment trench horizontally spaced apart from the transistor area by a predetermined distance,
first trenches disposed between adjacent through-electrodes in the transistor area, and
second trenches disposed to surround the transistor area,
wherein lower levels of the alignment trench, the first trenches, and the second trenches are at substantially the same level, and
the first semiconductor chip is vertically stacked on the base chip, and includes a first semiconductor substrate, a plurality of through-vias penetrating the first semiconductor substrate and forming a transistor area on the first semiconductor substrate, and first trenches disposed between adjacent through-vias in the transistor area.

15. The semiconductor package of claim 14, further comprising a molding member disposed on the base chip and surrounding a side surface of the first fillet layer and a side surface of the first semiconductor chip,
wherein lower levels of the first trenches and the second trenches are lower than a lower level of the upper protective layer.

16. The semiconductor package of claim 15, wherein a portion of the first fillet layer fills at least a portion of interiors of the first trenches, and
portions of the first fillet layer and the molding member fill at least a portion of interiors of the second trenches.

17. The semiconductor package of claim 14, wherein the second trenches have a sum of internal volumes greater than a sum of internal volumes of the first trenches.

18. The semiconductor package of claim 14, wherein each second trench
has a width greater than a width of each first trench,
extends in a longitudinal direction, and
is formed of at least one layer.

19. A semiconductor package comprising:
a base chip;
a first semiconductor chip on the base chip;
a first fillet layer between the base chip and the first semiconductor chip; and
a molding member disposed on the base chip and surrounding a side surface of the first fillet layer and a side surface of the first semiconductor chip,
wherein the base chip includes
a base substrate,
a plurality of through-electrodes penetrating the base substrate and providing a transistor area on the base substrate,
an upper protective layer surrounding the plurality of through-electrodes and covering an upper surface of the base substrate,
an alignment trench spaced apart from the transistor area in a horizontal direction and disposed near a vertex of an upper surface of the base chip,
first trenches disposed between adjacent through-electrodes in the transistor area and filled with the first fillet layer, and
second trenches disposed in an outer side portion of the transistor area and filled with the first fillet layer and the molding member,
wherein lower levels of the alignment trench, the first trenches, and the second trenches are at substantially the same level, and are at a level lower than a lower level of the upper protective layer, and
wherein the first fillet layer filled in the first trenches contacts the base substrate and forms a first heterogeneous interface, and the first fillet layer and the molding member filled in the second trenches contact the base substrate and form a second heterogeneous interface.

20. The semiconductor package of claim 19, wherein each second trench has a width greater than a width of each first trench.
